(19) United States
(12) Patent Application Publication
(10) Pub. No.: US 2024/0237223 A1
(43) Pub. Date: Jul. 11, 2024

(54) METHOD AND SYSTEM FOR GENERATING JET PRINTING DATA, ELECTRONIC DEVICE, AND STORAGE MEDIUM

(71) Applicant: Vayo (Shanghai) Technology Co., Ltd., Shanghai (CN)

(72) Inventors: Shengjie QIAN, Shanghai (CN); Jishuo LIU, Shanghai (CN); Fengshou LIU, Shanghai (CN)

(73) Assignee: Vayo (Shanghai) Technology Co., Ltd., Shanghai (CN)

(21) Appl. No.: 18/562,326

(22) PCT Filed: Apr. 11, 2022
(86) PCT No.: PCT/CN2022/086006

§ 371 Date: Nov. 19, 2023

(30) Foreign Application Priority Data
May 20, 2021 (CN) 202110552417.9

(51) Int. Cl. H05K 3/00; G06T 7/00; H05K 3/12

(52) U.S. Cl. CPC H05K 3/0005; G06T 7/0004; H05K 3/125; G06T 2207/20016; G06T 2207/30141; H05K 2203/0121; H05K 2203/013

(57) ABSTRACT

A method and system for generating jet printing data, an electronic device, and a storage medium are provided. The method includes: step 1: obtaining a pad pattern, wherein the pad pattern comprises several highlighted regions; step 2: determining an image scanning angle of each of the highlighted regions in the pad pattern; step 3: scanning and filling each of the highlighted regions based on the corresponding image scanning angle, to obtain a jet printing path; and step 4: generating jet printing data based on the jet printing path. In the method for generating jet printing data of the present disclosure, only a bare PCB or a Gerber file is needed so that the jet printing data can be rapidly and accurately generated and provided to the jet printing system, thereby maximizing the speed for generating jet printing programs, increasing program quality, and operating efficiency.

### FIELD OF THE INVENTION

The present disclosure belongs to the technical field of printed circuit boards, and specifically relates to a method and system for generating jet printing data, an electronic device, and a storage medium.

### BACKGROUND OF THE INVENTION

In the field of surface mount technology, the application of solder paste through printing and coating is a crucial step in the production process. The quality of electronic assembly circuit boards is directly influenced by how well this process is controlled. At present, there are two main methods for applying solder paste: stencil printing and spray printing. Spray printing of solder paste is a novel technique in solder paste application. It allows for the spraying of a specific thickness and volume of solder paste onto both flat and uneven printed circuit boards. This method can apply the optimal amount of solder paste needed for specific components, thereby achieving highly reliable soldering. With the advent of 3D printed boards and Package on Package (POP) soldering, traditional stencil printing techniques are becoming less effective. Solder paste spray printing technology not only overcomes the limitations of traditional stencil printing on 3D printed boards and POP, but it also enhances the precision of solder paste application since it is able to spray a specific required amount of solder paste for specific components.

During product development, changes to the printed board are quite common. Using stencil printing can lead to increased costs and extended product development cycles due to the need for new stencils with each change to the printed board. In contrast, spray printing equipment eliminates the need for creating new stencils as it sprays solder paste directly onto the Printed Circuit Board (PCB), and all that's needed is an adjustment to the spray printing program, which not only reduces costs but also shortens product development cycles.

Therefore, how to quickly and accurately establish spray printing data during the solder paste spray printing process is a key technical issue and an important technical challenge in this field.

### SUMMARY OF THE INVENTION

In light of the above problem existing in the related art, the present disclosure provides a method and system for generating jet printing data, an electronic device, and a storage medium.

The method comprises:
step 1: obtaining a pad pattern, wherein the pad pattern comprises several highlighted regions;
step 2: determining an image scanning angle of each of the highlighted regions in the pad pattern;
step 3: scanning and filling each of the highlighted regions based on the corresponding image scanning angle, to obtain a jet printing path; and
step 4: generating jet printing data based on the jet printing path.

As an example, step 1 comprises:
step 1.1: obtaining a to-be-jet-printed PCB image;
step 1.2: removing screen-printing patterns from the to-be-jet-printed PCB image to obtain a first image; and
step 1.3: processing the first image by using image binarization and denoising algorithms, to obtain the pad pattern comprising the highlighted regions.

As an example, step 1.3 comprises:
step 1.31: processing the first image by using a dilation and/or erosion algorithm, to obtain a second image; and
step 1.32: removing, from the second image, white spots whose minimum bounding rectangle has a size smaller than a preset size or which have an actual area smaller than a minimum threshold area, to obtain the pad pattern.

As an example, step 1 comprises:
obtaining the pad pattern through a Gerber file.

As an example, step 2 comprises:
step 2.1: step 2.1: determining whether a single highlighted region of the highlighted regions is a circle, wherein if yes, an image scanning angle of the single highlighted region is 0 degree, and if no, the single highlighted region is a polygon; and
step 2.2: processing the single highlighted region based on a relationship between an initial area ratio K and a minimum initial area ratio Kₘᵢₙ if the single highlighted region is a polygon, to obtain the image scanning angle of the single highlighted region, wherein K=(S/S₀)*100, S₀=L₀*W₀, L₀ is a length of the single highlighted region in a horizontal direction, W₀ is a width of the single highlighted region in a vertical direction, and S is an area of the single highlighted region.

As an example, step 2.1 comprises:
determining whether the single highlighted region is a circle, wherein if L₀ is greater than or equal to W₀, a length and width tolerance value is given by T=(L₀−W₀)/L₀, and if L₀ is less than W₀, T=(W₀−L₀)/W₀, and determining whether T is less than or equal to a maximum threshold Tₘₐₓ and whether an area ratio tolerance value T₁ is less than or equal to a maximum threshold T₁ₘₐₓ, wherein if T is less than or equal to Tₘₐₓ and T₁ is less than or equal to T₁ₘₐₓ, the single highlighted region is rotated by an angle n₁, and if T₂ is less than Tₘₐₓ, the single highlighted region is a circle, and the image scanning angle of the single highlighted region is 0 degree, otherwise, the single highlighted region is a polygon, wherein T₁=|K−(π/4)|, T₂=|L₁−W₁|/L₀, L₁ is a length of the single highlighted region in a horizontal direction after being rotated by the angle n₁, W₁ is a width of the single highlighted region in a vertical direction after being rotated by the angle n₁, and 0 degree<n₁<90 degrees.

As an example, step 2.2 comprises:
step 2.21: determining the relationship between the initial area ratio K and the minimum initial area ratio Kₘᵢₙ if the single highlighted region is a polygon, wherein if K is greater than or equal to Kₘᵢₙ, the single highlighted region is not rotated, if L₀ is greater than or equal to W₀ in this case, the image scanning angle of the single highlighted region is 0 degree, if L₀ is less than W₀, the image scanning angle of the single highlighted region is 90 degrees, and if K is less than Kₘᵢₙ, the single highlighted region is rotated according to step 2.22;
step 2.22: rotating the single highlighted region by an angle n for each rotation and determining a relationship between an area ratio K₁ and an minimum area ratio K₁ min after the single highlighted region is rotated by the angle n for each rotation, wherein if K₁ is greater than or equal to K₁ₘᵢₙ, the rotation of the single highlighted region is stopped, and magnitudes of L₂ and W₂ are determined; if L₂ is greater than or equal to W₂, the image scanning angle of the single highlighted region is a current rotation angle; if L₂ is less than W₂, the image scanning angle of the single highlighted region is the current rotation angle plus 90 degrees; if K₁ is less than K₁ₘᵢₙ, the single highlighted region continues to be rotated by the angle n; if K₁ is less than K₁ₘᵢₙ after rotation by the angle n for each rotation, a rotation angle corresponding to a maximum K₁ is selected as the current rotation angle of the single highlighted region, and magnitudes of L₂ and W₂ are determined; if L₂ is greater than or equal to W₂, the image scanning angle of the single highlighted region is the current rotation angle; and if L₂ is less than W₂, the image scanning angle of the single highlighted region is the current rotation angle plus 90 degrees, wherein K₁=(S/S₁)*100, S₁=L₂*W₂, L₂ is a length of the single highlighted region in the horizontal direction after being rotated by the angle n for each rotation, W₂ is a width of the single highlighted region in the vertical direction after being rotated by the angle n for each rotation, and 0 degree<n<90 degrees.

As an example, after step 2, the method further comprises:
performing downscaling or upscaling processing on the highlighted regions to obtain downscaled or upscaled highlighted regions.

As an example, the performing downscaling or upscaling processing on the highlighted region to obtain a downscaled or upscaled highlighted region comprises:
for each highlighted region, determining a relationship between M and 0, performing downscaling processing on the highlighted region if M is less than 0, to obtain a corresponding downscaled highlighted region, and performing upscaling processing on the highlighted region if M is greater than 0, to obtain a corresponding upscaled highlighted region, wherein M=K₂*a quantity of pixels, and K₂ is a positive value, a negative value, or 0.

An embodiment of the present disclosure further provides a system for generating jet printing data, comprising:
an obtaining module, configured to obtain a pad pattern, wherein the pad pattern comprises several highlighted regions;
a scanning angle generation module, configured to determine an image scanning angle of each of the highlighted regions in the pad pattern;
a jet printing path generation module, configured to scan and fill each of the highlighted region based on the corresponding image scanning angle, to obtain a jet printing path through a scanning algorithm; and
a jet printing data generation module, configured to generate jet printing data based on the jet printing path.

An embodiment of the present disclosure further provides an electronic device, comprising a processor, a communication interface, a memory, and a communication bus, wherein the processor, the communication interface, and the memory complete communication with each other through the communication bus;
the memory is configured to store a computer program; and
the processor is configured to implement the steps of the method for generating jet printing data as in any of the above embodiments during execution of the computer program.

An embodiment of the present disclosure further provides a storage medium, storing a computer program, the computer program, when executed by a processor, implementing the steps of the method for generating jet printing data as in any of the above embodiments.

The present disclosure has the following beneficial effects:

According to the method for generating jet printing data of the present disclosure, the image scanning angle of each highlighted region in the pad pattern is first determined, then each highlighted region is scanned and filled to determine a jet printing path, and finally jet printing data is generated based on the jet printing path, so that a jet printing system can perform a jet printing operation using the jet printing data. Therefore, in the method for generating jet printing data of the present disclosure, only a bare PCB or a Gerber file is needed so that the jet printing data can be rapidly and accurately generated and provided to the jet printing system, thereby maximizing the speed for generating jet printing programs, increasing program quality, and operating efficiency.

The jet printing data finally formed according to the method for generating jet printing data of the present disclosure may be device instruction data directly or indirectly used by a jet printing device.

The present disclosure is further described in detail below with reference to the embodiments and the accompanying drawings.

### BRIEF DESCRIPTION OF THE DRAWINGS

FIG. 1 is a flowchart illustrating a method for generating jet printing data according to an embodiment of the present disclosure.

FIG. 2 is a flowchart illustrating another method for generating jet printing data according to an embodiment of the present disclosure.

FIG. 3 is a schematic diagram of a line filling algorithm with an image scanning angle of 0 degree according to an embodiment of the present disclosure.

FIG. 4 is a schematic diagram of a line filling algorithm with an image scanning angle of 30 degrees according to an embodiment of the present disclosure.

FIG. 5 is a schematic diagram of a line filling algorithm with an image scanning angle of 90 degrees according to an embodiment of the present disclosure.

FIG. 6 is a schematic diagram of a dot filling algorithm with an image scanning angle of 0 degree according to an embodiment of the present disclosure.

FIG. 7 is a schematic diagram of a dot filling algorithm with an image scanning angle of 30 degrees according to an embodiment of the present disclosure.

FIG. 8 is a schematic diagram of a dot filling algorithm with an image scanning angle of 90 degrees according to an embodiment of the present disclosure.

FIG. 9 is a block diagram of a system for generating jet printing data according to an embodiment of the present disclosure.

FIG. 10 is a block diagram of an electronic device according to an embodiment of the present disclosure.

### DETAILED DESCRIPTION

The present disclosure is further described in detail below with reference to specific embodiments, but implementations of the present disclosure are not limited thereto.

### Embodiment I

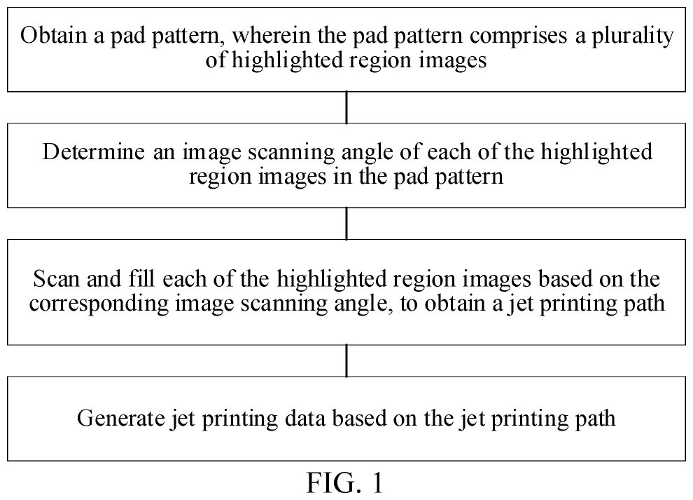

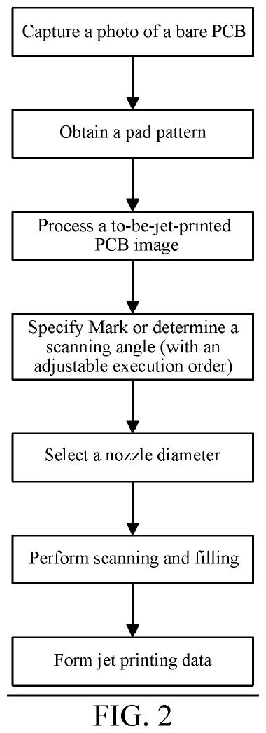

Refer to FIG. 1 and FIG. 2. FIG. 1 is a flowchart illustrating an exemplary method for generating jet printing data. FIG. 2 is a flowchart of another exemplary method for generating jet printing data. The method for generating jet printing data as shown in FIG. 1 comprise step 1 to step 5.

Step 1: obtaining a pad pattern, wherein the pad pattern comprises several highlighted regions, and each highlighted region is a region that needs to be printed.

For example, the pad pattern may be obtained in the following two manners, which are exemplary and not restrictive.

The first manner comprises step 1.1 to step 1.3.

Step 1.1: obtaining a to-be-jet-printed PCB image.

Specifically, a bare PCB is first fixed, then a photo of the bare PCB is captured using an industrial color camera, and then stored. The stored photo is the to-be-jet-printed PCB image.

Step 1.2: removing a screen-printing pattern from the to-be-jet-printed PCB image to obtain a first image.

Specifically, Step 1.2 may be performed according to characteristics of the to-be-jet-printed PCB image. Usually, screen-printing patterns are white, pad patterns are bright or gold, and PCBs are green, red, black, cyan, orange, etc. Therefore, in Step 1.2, the screen-printing pattern may be removed by removing white parts of the total pattern, that is, white pixels are converted into black pixels.

Step 1.3: processing the first image by using image binarization and denoising algorithms, to obtain the pad pattern comprising the several highlighted regions.

Step 1.31: processing the first image by using a dilation and/or erosion algorithm, to obtain a second image.

Specifically, since particles such as dust may gather on the PCB during photographing, and corresponding small black spots may appear on the photo. The small black spots need to be removed. In addition, the PCB may have light reflections on its surface during photographing, which may cause small white spots to appear on the photo, and therefore denoising is needed. Therefore, the small black spots or small white spots on the first image may be removed by using the dilation and/or erosion algorithm, to obtain the second image.

Step 1.32: Removing, from the second image, white spots whose minimum bounding rectangle has a size smaller than a preset size or which have an actual area smaller than a minimum threshold area, to obtain the pad pattern.

Specifically, relatively large white spots in the second image are removed. If the size of the minimum bounding rectangle of a white spot is less than the preset size, this white spot is removed (for example, when the white spot is larger than a pixel and smaller than a solder pad, it is removed). If the actual area of a white spot is less than the threshold area, this white spot is also removed. The pattern with the white spots being removed is the pad pattern. Herein, a minimum bounding rectangle is the smallest rectangle that encompasses an entire white spot. The actual area of a white spot=a quantity of pixels of the white spot*area of a single pixel.

Preferably, the preset size is 0.07 mm*0.2 mm, wherein 0.07 mm is a width, and 0.2 mm is a length.

Preferably, the minimum threshold area S_{threshold}=0.014 mm².

The second manner comprises obtaining the pad pattern through a Gerber file.

Step 2: determining an image scanning angle of each of the highlighted regions in the pad pattern.

Specifically, step 2 may comprise step 2.1 to step 2.2.

Step 2.1: determining whether each single highlighted region of the several highlighted regions is a circle, wherein if yes, an image scanning angle of this single highlighted region is 0 degree, and if no, this single highlighted region is a polygon.

For each single highlighted region, if L₀ is greater than or equal to W₀, a length and width tolerance value T=(L₀−W₀)/L₀. If L₀ is less than W₀, T=(W₀−L₀)/W₀, it is determined whether T is less than or equal to a maximum threshold Tₘₐₓ and whether an area ratio tolerance value T₁ is less than or equal to a maximum threshold T₁ₘₐₓ. If T is less than or equal to Tₘₐₓ and T₁ is less than or equal to T₁ₘₐₓ (that is, T₁≤ T₁ₘₐₓ), the single highlighted region is rotated by an angle n₁ (rotated only once). If T₂ is less than Tₘₐₓ, the single highlighted region is a circle, and the image scanning angle of the single highlighted region is 0 degree, otherwise, the single highlighted region is a polygon. T₁=|K−(π/4)|, K=(S/S₀)*100, S₀=L₀*W₀, L₀ is a length of the single highlighted region in a horizontal direction, W₀ is a width of the single highlighted region in a vertical direction, and S is an area of the single highlighted region. The area S of the single highlighted region=a quantity of pixels of the single highlighted region *an area of a single pixel, T₂=|L₁−W₁|/L₀, L₁ is a length of the single highlighted region in the horizontal direction after being rotated by the angle n₁, W₁ is a width of the single highlighted region in the vertical direction after being rotated by the angle n₁, and 0 degree<n₁<90 degrees.

Preferably, Tₘₐₓ=1%.

Preferably, the value of T₁ₘₐₓ is in a range of 0.01 to 0.05 (including the endpoints). That is to say, a person skilled in the art may choose a value from the range of 0.01 to 0.05 as the value of the maximum threshold T₁ₘₐₓ based on practical needs.

Preferably, n₁ is 45 degrees.

It should be noted that, the single highlighted region may be rotated clockwise or counterclockwise.

Step 2.2: processing the single highlighted region based on a relationship between an initial area ratio K and a minimum initial area ratio Kₘᵢₙ if the single highlighted region is a polygon, and accordingly obtaining the image scanning angle of the single highlighted region.

Step 2.21: determining the relationship between the initial area ratio K and the minimum initial area ratio Kₘᵢₙ if the single highlighted region is a polygon, wherein if K is greater than or equal to Kₘᵢₙ, the single highlighted region is not rotated, in which case, if L₀ is greater than or equal to W₀, the image scanning angle of the single highlighted region is 0 degree, and if L₀ is less than W₀, the image scanning angle of the single highlighted region is 90 degrees, wherein if K is less than Kₘᵢₙ, the single highlighted region is rotated according to step 2.22.

Preferably, Kₘᵢₙ=90.

Step 2.22: rotating the single highlighted region by an angle n for each rotation (each rotation continues based on the previous rotation) and determining a relationship between an area ratio K₁ and an minimum area ratio K₁ₘᵢₙ for each rotation after the single highlighted region is rotated by the angle n, wherein if K₁ is greater than or equal to K₁ₘᵢₙ, the rotation of the single highlighted region is stopped, and magnitudes of L₂ and W₂ are determined; if L₂ is greater than or equal to W₂, the image scanning angle of the single highlighted region is a current rotation angle; if L₂ is less than W₂, the image scanning angle of the single highlighted region is the current rotation angle plus 90 degrees; if K₁ is less than K₁ₘᵢₙ, the single highlighted region continues to be rotated by the angle n; if after each rotation by the angle n, K₁ remains less than K₁ₘᵢₙ (that is, K₁ is still less than K₁ₘᵢₙ after rotation by 0 degree to 90 degrees (excluding 0 degree and 90 degrees) in total), a rotation angle corresponding to a maximum K₁ is selected as the current rotation angle of the single highlighted region, and magnitudes of L₂ and W₂ are determined; if L₂ is greater than or equal to W₂, the image scanning angle of the single highlighted region is the current rotation angle; and if L₂ is less than W₂, the image scanning angle of the single highlighted region is the current rotation angle plus 90 degrees, wherein K₁=(S/S₁)*100, S₁=L₂*W₂, L₂ is a length of the single highlighted region in a horizontal direction after being rotated by the angle n for each rotation, W₂ is a width of the single highlighted region in a vertical direction after being rotated by the angle n for each rotation, and 0 degree<n<90 degrees.

Preferably, K₁ min=98.

Preferably, n may be 45 degrees, 15 degrees, 30 degrees, or 60 degrees, or n may be any angle selected from the range of 0 degree to 90 degrees based on practical needs.

It should be noted that, for a person skilled in the art, the angle n for each rotation may be varied adjustable.

Step 3: performing downscaling or upscaling processing on the highlighted regions to obtain downscaled or upscaled highlighted regions.

Specifically, for each single highlighted region, a relationship between M and 0 is determined. If M is less than 0, this single highlighted region is downscaled to obtain a downscaled highlighted region, and if M is greater than 0, this single highlighted region is upscaled to obtain an upscaled highlighted region. If M is 0, this single highlighted region does not need to be downscaled or upscaled, wherein M=K₂*a quantity of pixels, and K₂ is a positive value, a negative value, or 0.

As an example, the number of pixels by which the single highlighted image needs to be downscaled or upscaled can be further obtained based on M=K₂*the quantity of pixels. Specifically, as an example, the number of pixels of the single highlighted region is increased (when M is positive) or reduced (when M is negative) by |M| based on an image outlining algorithm, to achieve upscaling or downscaling.

Further, when the single highlighted region is a circle, if an area S of the single highlighted region is in a range of 0 square millimeters to 0.5 square millimeters, K₂₌₅%; if the area S of the single highlighted region is in a range of 0.5 square millimeters to 1 square millimeter, K₂₌₀%; and if the area S of the single highlighted region is in a range of 1 square millimeter to ∞ square millimeters, K₂=−5%. When the single highlighted region is a polygon, if the area S of the single highlighted region is in a range of 0 square millimeters to 1.0 square millimeter, K₂=0%; if the area S of the single highlighted region is in a range of 1.0 square millimeter to 3.6 square millimeters, K₂=−5%; if the area S of the single highlighted region is in a range of 3.6 square millimeters to 7.0 square millimeters, K₂=−10%; and if the area S of the single highlighted region is in a range of 7.0 square millimeters to ∞ square millimeters, K₂=−15%.

In addition, it should be noted that, before or after the image scanning angle of each single highlighted region is determined, Mark point positions may further be specified through the highlighted regions. An order of specifying the Mark point position and a manner of specifying the Mark point position may be adjusted according to practical needs.

Moreover, as an example, a nozzle diameter may be selected based on the actual jet printing device to be used. An order of selecting the nozzle diameter may be adjusted according to practical needs.

Step 4: scanning and filling downscaled or upscaled highlighted regions, to obtain a jet printing path.

Specifically, the downscaled or upscaled highlighted regions may be scanned and filled by using a dot filling algorithm or a line filling algorithm, and then the jet printing path is obtained through a scanning algorithm. The jet printing path is represented by the obtained scan, and an order is obtained through division of grid regions.

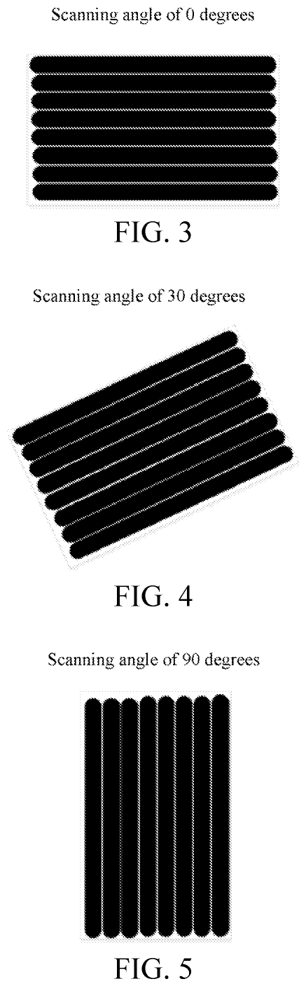

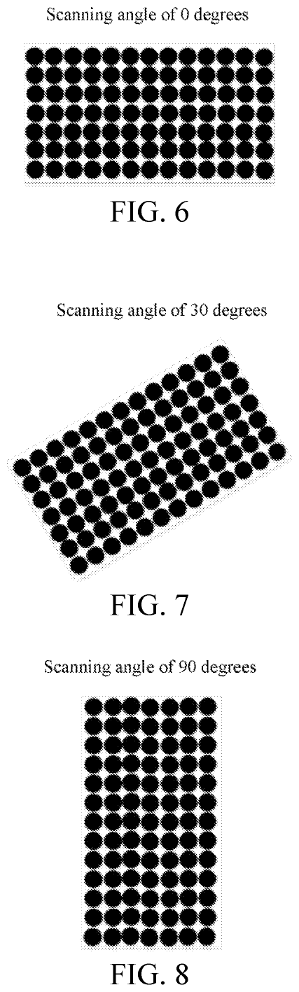

Specifically, the manner of scanning and filling as an example may be the dot filling algorithm or the line filling algorithm. The dot filling algorithm comprises filling a dot matrix at different image scanning angles based on the selected nozzle diameter, and the line filling algorithm comprises arranging and filling lines at different image scanning angles based on the selected nozzle diameter. For example, referring to FIG. 3 to FIG. 5, the filling is performed at image scanning angles of 0 degree, 30 degrees, and 90 degrees by using the line filling algorithm. Referring to FIG. 6 to FIG. 8, the filling is performed at image scanning angles of 0 degree, 30 degrees, and 90 degrees by using the dot filling algorithm.

For dot filling, the jet printing path requires coordinates of each dot, while for line filling, motion positions of the filling comprise a start position and an end position of each scanning line.

It should be noted that, when one or more highlighted regions need to be downscaled or upscaled, the downscaled or upscaled highlighted regions need to be scanned and filled, to obtain the jet printing path.

Step 5: generating jet printing data based on the jet printing path.

Specifically, data obtained through the above conversion is processed into the jet printing data. The jet printing data not only comprises the jet printing path (that is, a nozzle motion trajectory), but also comprises: Mark point positions, jetting enabling and disabling instructions (i.e., instructions to enable and disable jetting), and a jet printing diameter (that is, a nozzle diameter); instruction data received and used by the jet printing device may be directly or indirectly formed by the jet printing data.

Therefore, in the method for generating jet printing data of the present disclosure, only a bare PCB or a Gerber file is needed so that the jet printing data can be rapidly and accurately generated and provided to the jet printing system, thereby maximizing the speed for generating jet printing programs, increasing program quality, and operating efficiency.

The data finally formed in the present disclosure may be device instruction data directly used by the jet printing device. In the present disclosure, the jet printing device may be one or more of an inkjet printer, an electrohydrodynamic (EHD) jet printer, a 3D printer, and a LaserJet printer.

### Embodiment II

This embodiment further provides a specific method for generating jet printing data based on the above embodiment. The method for generating jet printing data comprises the following steps:

S1: fixing a bare PCB and capture a photo of the bare PCB by using an industrial color camera.

S2: storing the photo captured by the industrial camera, wherein the stored photo is a to-be-jet-printed PCB image.

S3: obtaining a pad pattern, by:
removing a screen-printing pattern from the to-be-jet-printed PCB image and then performing image binarization and denoising, to obtain highlighted regions. Specifically, S3 comprises S3.1 and S3.2.

S3.1: removing the screen-printing pattern from the to-be-jet-printed PCB image based on colors of the PCB image (exemplary colors: screen-printing pattern: white; pad: bright color; PCB: green), and removing white parts of the PCB image (for example, the white parts are converted to black).

S3.2: setting a value of bright pixels to 1, and set values of black and green pixels to 0 by using image binarization and denoising algorithms, wherein specifically, (1) is performed first, and then (2) is performed:
(1) using an image processing algorithm, where small black spots (for example, particles such as dust gather on a PCB during photographing, causing black spots on the photo) are removed from the image through a dilation and/or erosion algorithm, or small white spots (for example, light reflections cause small white spots on the photo, and therefore denoising is needed) are removed.
(2) setting a minimum threshold area S_{threshold}=0.014 mm², so that relatively large white spots are removed. If a minimum bounding rectangle of a white spot has a size smaller than 0.07 mm*0.2 mm or an actual area less than S_{threshold}, this white spot is removed.

S4: specifying Mark point positions based on each of obtained highlighted regions, wherein the order of specifying the Mark point positions and determining the image scanning angle of each highlighted region is adjustable. For example:
S4.1: selecting the Mark point positions.
S4.2. determining the image scanning angle of each highlighted region.

A length L₀ and a width W₀ of each single highlighted region are obtained in a horizontal direction and a vertical direction, respectively, a bounding rectangle of the single highlighted region is obtained based on L₀ and W₀, and an area of the bounding rectangle is given by S₀=L₀*W₀.

An area of the single highlighted region is given by S=a quantity of pixels*an area of a single pixel.

An initial area ratio is given by K=(S/S₀)*100.

It is then determined whether the single highlighted region is a circle. If L₀ is greater than or equal to W₀, a length and width tolerance value is given by T=(L₀−W₀)/L₀. If L₀ is less than W₀, T=(W₀−L₀)/W₀. It is then determined whether T is less than or equal to 1% and whether an area ratio tolerance value T₁=|K−(π/4)| is less than or equal to 0.05. If T is less than or equal to 1% and T₁ is less than or equal to 0.05, the single highlighted region is rotated by a rotation angle of n₁ (n₁ is in a range of 0 degree to 90 degrees, excluding 0 degree and 90 degrees, preferably 45 degrees). In this case, the single highlighted region is rotated only once, to obtain a length L₁ and a width W₁ of the rotated single highlighted region in a horizontal direction and a vertical direction, respectively, and T₂=|L₁−W₁|/L₀. It is then determined whether T₂ is less than 1%. If T₂ is less than 1%, the single highlighted region is a circle, and the corresponding image scanning angle is 0 degree. Otherwise, the single highlighted region is a polygon.

If the single highlighted region is a polygon, a relationship between the initial area ratio K and 96 is determined. If K is greater than or equal to 96, the single highlighted region does not need to be rotated, and magnitudes of L₀ and W₀ are determined. If L₀ is greater than or equal to W₀, it is determined that the image scanning angle is 0 degree. If L₀ is less than W₀, it is determined that the image scanning angle is 90 degrees. If the initial area ratio K is less than 96, the single highlighted region starts to be rotated.

The single highlighted region is rotated to obtain a rotated single highlighted region, with a length L₂ and a width W₂ in the horizontal direction and the vertical direction, respectively. One bounding rectangle is obtained for each rotation the single highlighted region is rotated by a rotation angle of n, and a length and a width of this bounding rectangle correspond to the rotated single highlighted region (a range of the rotation angle n: 0 degree to 90 degrees, excluding 0 degree and 90 degrees). The rotation angle within this range is preferably 45 degrees, 15 degrees, 30 degrees, and 60 degrees. If the above angles cannot preferably satisfy an area ratio, rotation is performed based on n degrees for each rotation (the rotation angle n for each rotation is adjustable based on practical needs).

The area ratio is given by K₁=(an area S of the single highlighted region/an area S₁ of the bounding rectangle obtained through rotation of the single highlighted region)*100.

The area S₁ of the bounding rectangle obtained through rotation of the single highlighted region=the length L₂*the width W₂.

It is then determined whether the area ratio K₁ is greater than or equal to 99. If yes, the rotation of the single highlighted region is stopped, a current rotation angle is obtained, and magnitudes of L₂ and W₂ are determined, in which case, if L₂ is greater than or equal to W₂, the current rotation angle is the image scanning angle, and if L₂ is less than W₂, it is determined that the image scanning angle is the current rotation angle plus 90 degrees. If the area ratio K₁ is not greater than or equal to 99, the single highlighted region continues to be rotated. If area ratios corresponding to 0 degree to 90 degrees (excluding 0 degree and 90 degrees) are all less than 99, a maximum corresponding angle of K₁ is taken as the current rotation angle and the magnitudes of L₂ and W₂ are determined, in which case, if L₂ is greater than or equal to W₂, the current rotation angle is the image scanning angle, and if L₂ is less than W₂, it is determined that the image scanning angle is the current rotation angle plus 90 degrees.

S5: performing downscaling or upscaling processing on the highlighted regions to obtain downscaled or upscaled highlighted regions.

Shape: a circle and a polygon.

### (1) Circle:

The area S of the single highlighted region is obtained, and K₂ is obtained based on the area S.
1>. Range of the area S: 0-0.5 square millimeters, K₂₌₅%.
2>. Range of the area S: 0.5-1 square millimeters, K₂₌₀%.
3>. Range of the area S: 1-0 square millimeters, K₂=−5%.

### (2) Polygon:

The area S of the single highlighted region is obtained, and K₂ is obtained based on the area S.
1>. Range of the area S: 0-1.0 square millimeters, K₂=0%.
2>. Range of the area S: 1.0-3.6 square millimeters, K₂=−5%.
3>. Range of the area S: 3.6-7.0 square millimeters, K₂=−10%.
4>. Range of the area S: 7.0-∞ square millimeters, K₂=−15%.

As an example, the number of pixels by which the single highlighted image needs to be downscaled or upscaled can be further obtained based on M=K₂*the quantity of pixels. Specifically, as an example, the number of pixels of the single highlighted region is increased (when M is positive) or reduced (when M is negative) by |M| based on an image outlining algorithm, to achieve upscaling or downscaling.

S6: selecting a nozzle diameter.

S7: scanning and filling the downscaled or upscaled highlighted regions, and obtain a jet printing path through a scanning algorithm.

### Scanning Algorithm:

Dot filling algorithm: filling a dot matrix at different image scanning angles based on the selected nozzle diameter.

Line filling algorithm: arranging and filling lines at different image scanning angles based on the selected nozzle diameter.

### Jet Printing Path:

Motion positions: comprising a start position and an end position of each scanning line.

Dot filling: requiring coordinates of each dot.

S8: generating jet printing data, wherein data obtained through conversion in S₁ to S7 is processed into the jet printing data, and the jet printing data comprises: Mark point positions, a nozzle motion trajectory, jetting enabling and disabling instructions, a jet printing diameter, and device instruction data directly formed by the jet printing data.

In addition, the pad pattern as an example may also be obtained through a Gerber file, and then S4 to S8 are performed to form the jet printing data.

### Embodiment III

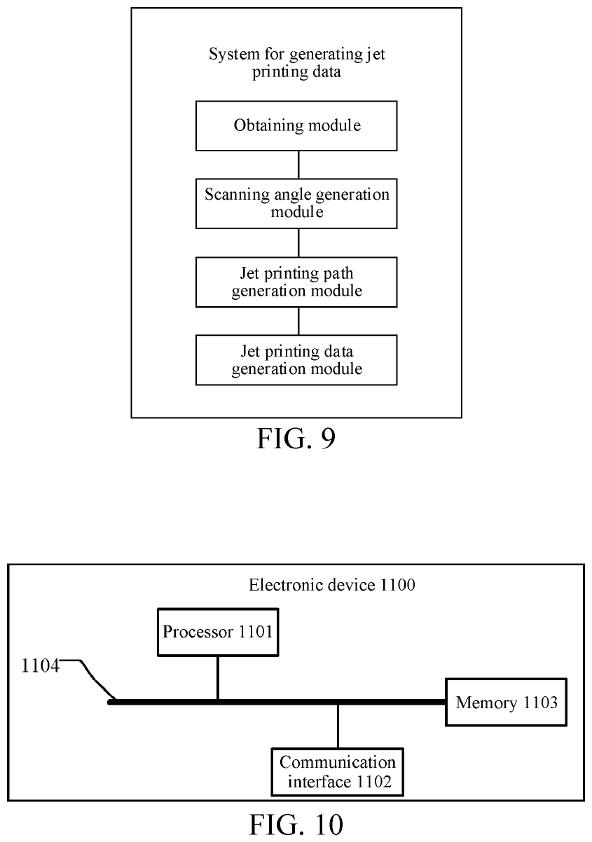

Referring to FIG. 9, FIG. 9 is a block diagram of a system for generating jet printing data according to an embodiment of the present disclosure. The system for generating jet printing data comprises:
an obtaining module, configured to obtain a pad pattern, wherein the pad pattern comprises several highlighted regions;
a scanning angle generation module, configured to determine an image scanning angle of each of the highlighted regions in the pad pattern;
a jet printing path generation module, configured to scan and fill each of the highlighted regions based on the corresponding image scanning angle, to obtain a jet printing path through a scanning algorithm; and
a jet printing data generation module, configured to generate jet printing data based on the jet printing path.

The system for generating jet printing data provided, as an example, may perform the above method embodiments with similar implementation principles and technical effects.

### Embodiment IV

Refer to FIG. 10, which is a block diagram of an electronic device according to this embodiment. The electronic device 1100 comprises a processor 1101, a communication interface 1102, a memory 1103, and a communication bus 1104. The processor 1101, the communication interface 1102, and the memory 1103 complete communication with each other through the communication bus 1104.

The memory 1103 is configured to store a computer program.

The processor 1101 is configured to implement the steps of the above method during execution of the computer program.

The processor 1101 is configured to implement the following steps during execution of the computer program.

Step 1: obtaining a pad pattern, wherein the pad pattern comprises several highlighted regions.

Step 2: determining an image scanning angle of each of the highlighted regions in the pad pattern.

Step 3: scanning and fill each of the highlighted regions based on the corresponding image scanning angle, to obtain a jet printing path.

Step 4: generating jet printing data based on the jet printing path.

The electronic device of the present disclosure may perform the above method embodiments with similar implementation principles and technical effects.

### Embodiment V

This embodiment provides a computer-readable storage medium, storing a computer program. The computer program, when executed by a processor, implements the following steps.

Step 1: obtaining a pad pattern, wherein the pad pattern comprises several highlighted regions.

Step 2: determining an image scanning angle of each of the highlighted regions in the pad pattern.

Step 3: scanning and filling each of the highlighted regions based on the corresponding image scanning angle, to obtain a jet printing path.

Step 4: generating jet printing data based on the jet printing path.

The computer-readable storage medium provided as an example of the present disclosure may perform the above method embodiments with similar implementation principles and technical effects, and details are not described herein again.

A person skilled in the art should understand that the embodiments of the present disclosure may be provided as a method, an apparatus (a device), or a computer program product. Therefore, the present disclosure may be in the form of hardware-only embodiments, software-only embodiments, or embodiments combining software and hardware, which are all collectively referred to as “modules” or “systems”. Moreover, the present disclosure may be in the form of a computer program product implemented on one or more computer-readable storage media (comprising but not limited to a disk memory, a CD-ROM, an optical memory, and the like) that comprise computer-usable program code. Computer programs are stored/distributed in suitable media, are provided together with other hardware or as a part of hardware, or may be distributed in other manners, for example, through the Internet or another wired or wireless telecommunications system.

In the description of the present disclosure, it should be noted that, the terms “first” and “second” are merely used for description and are not to be construed as indicating or implying relative importance or implicitly indicating the number of indicated technical features. Therefore, a feature limited by “first” or “second” may explicitly or implicitly comprise one or more of the features. In the descriptions of the present disclosure, the “plurality of” means two or more, unless otherwise definitely and specifically defined.

In the description of this specification, the description of the reference terms “an embodiment”, “some embodiments”, “an example”, “a specific example”, “some examples,” and the like means that specific features, structures, materials, or characteristics described in combination with the embodiment(s) or example(s) are comprised in at least one embodiment or example of the present disclosure. In this specification, schematic descriptions of the foregoing terms are not necessarily directed at the same embodiment or example. In addition, the described specific features, structures, materials, or characteristics may be combined in a proper manner in any one or more of the embodiments or examples. In addition, a person skilled in the art may integrate and combine different embodiments or examples described in this specification.

The above content is a further detailed description of the present disclosure in combination with specific preferred implementations, but it should not be considered that the specific implementation of the present disclosure is only limited to these descriptions. Various simple derivations or replacements may further be made by a person of ordinary skill in the art to which the present disclosure belongs without departing from the concept of the present disclosure, and shall fall within the scope of the present disclosure.

1. A method for generating jet printing data, comprising:
step 1: obtaining a pad pattern, wherein the pad pattern comprises several highlighted regions;
step 2: determining an image scanning angle of each of the highlighted regions in the pad pattern;
step 3: scanning and filling each of the highlighted regions based on the corresponding image scanning angle, to obtain a jet printing path; and
step 4: generating jet printing data based on the jet printing path.

2. The method for generating jet printing data as in claim 1, wherein step 1 comprises:
step 1.1: obtaining a to-be-jet-printed PCB image;
step 1.2: removing screen-printing patterns from the to-be-jet-printed PCB image to obtain a first image; and
step 1.3: processing the first image by using image binarization and denoising algorithms, to obtain the pad pattern comprising the highlighted regions.

3. The method for generating jet printing data as in claim 2, wherein step 1.3 comprises:
step 1.31: processing the first image by using a dilation and/or erosion algorithm, to obtain a second image; and
step 1.32: removing, from the second image, white spots whose minimum bounding rectangle has a size smaller than a preset size or which have an actual area smaller than a minimum threshold area, to obtain the pad pattern.

4. The method for generating jet printing data as in claim 1, wherein step 1 comprises:
obtaining the pad pattern through a Gerber file.

5. The method for generating jet printing data as in claim 1, wherein step 2 comprises:
step 2.1: determining whether a single highlighted region of the highlighted regions is a circle, wherein if yes, an image scanning angle of the single highlighted region is 0 degree, and if no, the single highlighted region is a polygon; and
step 2.2: processing the single highlighted region based on a relationship between an initial area ratio K and a minimum initial area ratio Kₘᵢₙ if the single highlighted region is a polygon, to obtain the image scanning angle of the single highlighted region, wherein K=(S/S₀)*100, S₀=L₀*W₀, L₀ is a length of the single highlighted region in a horizontal direction, W₀ is a width of the single highlighted region in a vertical direction, and S is an area of the single highlighted region.

6. The method for generating jet printing data as in claim 5, wherein step 2.1 comprises:
determining whether the single highlighted region is a circle, wherein if L₀ is greater than or equal to W₀, a length and width tolerance value is given by T=(L₀−W₀)/L₀, and if L₀ is less than W₀, T=(W₀−L₀)/W₀, and determining whether T is less than or equal to a maximum threshold Tₘₐₓ and whether an area ratio tolerance value T₁ is less than or equal to a maximum threshold T₁ₘₐₓ, wherein if T is less than or equal to Tₘₐₓ and T₁ is less than or equal to T₁ₘₐₓ, the single highlighted region is rotated by an angle n₁, and if T₂ is less than Tₘₐₓ, the single highlighted region is a circle, and the image scanning angle of the single highlighted region is 0 degree, otherwise, the single highlighted region is a polygon, wherein T₁=|K−(π/4)|, T₂=|L₁−W₁|/L₀, L₁ is a length of the single highlighted region in a horizontal direction after being rotated by the angle n₁, W₁ is a width of the single highlighted region in a vertical direction after being rotated by the angle n₁, and 0 degree<n_{1<90} degrees.

7. The method for generating jet printing data as in claim 5, wherein step 2.2 comprises:
step 2.21: determining the relationship between the initial area ratio K and the minimum initial area ratio Kₘᵢₙ if the single highlighted region is a polygon, wherein if K is greater than or equal to Kₘᵢₙ, the single highlighted region is not rotated, if L₀ is greater than or equal to W₀ in this case, the image scanning angle of the single highlighted region is 0 degree, if L₀ is less than W₀, the image scanning angle of the single highlighted region is 90 degrees, and if K is less than Kₘᵢₙ, the single highlighted region is rotated according to step 2.22;
step 2.22: rotating the single highlighted region by an angle n for each rotation and determining a relationship between an area ratio K₁ and an minimum area ratio K₁ min after the single highlighted region is rotated by the angle n for each rotation, wherein if K₁ is greater than or equal to K₁ min, the rotation of the single highlighted region is stopped, and magnitudes of L₂ and W₂ are determined; if L₂ is greater than or equal to W₂, the image scanning angle of the single highlighted region is a current rotation angle; if L₂ is less than W₂, the image scanning angle of the single highlighted region is the current rotation angle plus 90 degrees; if K₁ is less than K₁ₘᵢₙ, the single highlighted region continues to be rotated by the angle n; if K₁ is less than K₁ₘᵢₙ after rotation by the angle n for each rotation, a rotation angle corresponding to a maximum K₁ is selected as the current rotation angle of the single highlighted region, and magnitudes of L₂ and W₂ are determined; if L₂ is greater than or equal to W₂, the image scanning angle of the single highlighted region is the current rotation angle; and if L₂ is less than W₂, the image scanning angle of the single highlighted region is the current rotation angle plus 90 degrees, wherein K₁=(S/S₁)*100, S1=L₂*W₂, L₂ is a length of the single highlighted region in the horizontal direction after being rotated by the angle n for each rotation, W₂ is a width of the single highlighted region in the vertical direction after being rotated by the angle n for each rotation, and 0 degree<n<90 degrees.

8. The method for generating jet printing data as in claim 1, wherein after step 2, the method further comprises:
performing downscaling or upscaling processing on the highlighted regions to obtain downscaled or upscaled highlighted regions.

9. The method for generating jet printing data as in claim 8, wherein the performing downscaling or upscaling processing on the highlighted regions to obtain the downscaled or upscaled highlighted regions comprises:
for each highlighted region, determining a relationship between M and 0, performing downscaling processing on the highlighted region if M is less than 0, to obtain a corresponding downscaled highlighted region, and performing upscaling processing on the highlighted region if M is greater than 0, to obtain a corresponding upscaled highlighted region, wherein M=K₂*a quantity of pixels, and K₂ is a positive value, a negative value, or 0.

10. A system for generating jet printing data, comprising:
an obtaining module, configured to obtain a pad pattern, wherein the pad pattern comprises several highlighted regions;
a scanning angle generation module, configured to determine an image scanning angle of each of the highlighted regions in the pad pattern;
a jet printing path generation module, configured to scan and fill each of the highlighted regions based on the corresponding image scanning angle, to obtain a jet printing path through a scanning algorithm; and
a jet printing data generation module, configured to generate jet printing data based on the jet printing path.

11. An electronic device, comprising a processor, a communication interface, a memory, and a communication bus, wherein the processor, the communication interface, and the memory complete communication with each other through the communication bus;
the memory is configured to store a computer program; and
the processor is configured to implement the steps of the method of claim 1 during execution of the computer program.

12. A storage medium, storing a computer program, the computer program, when executed by a processor, implementing the steps of the method of claim 1.
